(19) United States
(12) Patent Application Publication
(10) Pub. No.: US 2016/0351799 A1
(43) Pub. Date: Dec. 1, 2016

(54) HARD MASK FOR PATTERNING MAGNETIC TUNNEL JUNCTIONS

(71) Applicant: Applied Materials, Inc., Santa Clara, CA (US)

(72) Inventors: Lin XUE, Sunnyvale, CA (US); Mahendra PAKALA, Fremont, CA (US); Hao CHEN, Santa Clara, CA (US); Jaesoo AHN, Fremont, CA (US)

(21) Appl. No.: 14/755,964

(22) Filed: Jun. 30, 2015

Related U.S. Application Data
(60) Provisional application No. 62/168,756, filed on May 30, 2015.

(51) Int. Cl. H01L 43/12; H01L 43/08; H01L 43/02

(52) U.S. Cl. CPC H01L 43/12; H01L 43/02; H01L 43/08

(57) ABSTRACT

Device structures and methods for fabricating device structures are provided herein. Magnetic random access memory (MRAM) devices described herein may include a film stack comprising a magnetic tunneling junction layer, a dielectric capping layer, an etch stop layer, a conductive hard mask layer, a dielectric hard mask layer, a spin on carbon layer, and an anti-reflective coating layer. The film stack may be etched by one or more selected chemistries to achieve improved film stack sidewall verticality. Memory cells having increasingly uniform and reduced critical dimensions may be fabricated utilizing the methods and devices described herein.

### CROSS-REFERENCE TO RELATED APPLICATIONS

This application claims benefit of U.S. Provisional Patent Application No. 62/168,756, filed May 30, 2015, the entirety of which is herein incorporated by reference.

### BACKGROUND

### Field

Embodiments of the present disclosure generally relate to device structures and methods for forming device structures. More specifically, embodiments described herein relate to hard masks for patterning magnetic tunnel junctions (MTJs).

### Description of the Related Art

Microelectronic devices are generally fabricated on a semiconductor substrate as integrated circuits. An example of such a device is a magnetic random access memory (MRAM). An MRAM device generally includes magnetic multilayer film stacks which are used as storage elements. The film stacks are typically a stack of different layers composed of various material, for example, permalloy (NiFe), cobalt iron (CoFe), tantalum (Ta), copper (Cu) and the like. The film stacks may also contain insulator materials such as aluminum oxide as a thin tunneling layer sandwiched between the layers of the film stack. The layers are typically deposited sequentially as overlying blanketed films. The film are subsequently patterned by various etching processes in which one or more layers of the film stack are removed, either partially or totally, in order to form a device feature.

One type of MRAM is spin-transfer-torque magnetic random access memory (STT-MRAM). Conventional STT-MRAM fabrication processes generally utilize photoresist materials as masks and reactive ion etching (RIE) to open hard masks which results in the hard masks having tapered sidewalls. As the pitch between neighboring MTJs continually shrinks for increasingly high density STT-MRAM devices, tapered sidewalls of hard masks formed by conventional processes reduce the space between neighboring MTJs. As a result, etching of the MTJs becomes increasingly difficult and adjacent MTJs are insufficiently separated, which causes reduced device yield and increases the probability of device failure.

Thus, what is needed in the art are film stacks and fabrication processes which provide for improved MRAM devices.

### SUMMARY

In one embodiment, a film stack is provided. The film stack includes a magnetic tunneling junction layer, a dielectric capping layer disposed on the magnetic tunneling junction layer, and an etch stop layer disposed on the dielectric capping layer. A conductive hard mask layer may be disposed on the etch stop layer and a dielectric hard mask layer may be disposed on the conductive hard mask layer. A spin on carbon layer may be disposed on the dielectric hard mask layer and an anti-reflective coating layer may be disposed on the spin on carbon layer.

In another embodiment, a film stack is provided. The film stack includes a magnetic tunneling junction layer and a dielectric capping layer disposed on the magnetic tunneling junction layer. A thickness of the dielectric capping layer may be between about 5 Å and about 20 Å. An etch stop layer may be disposed on the dielectric capping layer and a conductive hard mask layer may be disposed on the etch stop layer. A thickness of the etch stop layer may be between about 5 Å and about 50 Å and a thickness of the conductive hard mask layer may be between about 400 Å and about 1000 Å. A dielectric hard mask layer may be disposed on the conductive hard mask layer, a spin on carbon layer may be disposed on the dielectric hard mask layer, and an anti-reflective coating layer may be disposed on the spin on carbon layer.

In yet another embodiment, a method of etching a film stack is provided. The method includes patterning a photoresist layer and etching an anti-reflective coating layer of a film stack, etching a spin on carbon layer of the film stack using the anti-reflective coating layer as first a mask, and etching a dielectric hard mask layer of the film stack using the spin on carbon layer as second mask. A conductive hard mask layer of the film stack may be etched using the dielectric hard mask layer as a third mask and an etch stop layer of the film stack may be etched using the conductive hardmask layer as a fourth mask to expose a dielectric capping layer of the film stack. The dielectric capping layer may be disposed on a magnetic tunneling junction layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic view of a film stack with a patterned resist layer according to embodiments described herein.

FIG. 2 illustrates a schematic view of the film stack of FIG. 1 after etching a layer in the stack according to embodiments described herein.

FIG. 3 illustrates a schematic view of the film stack of FIG. 2 after etching a layer in the stack according to embodiments described herein.

FIG. 4 illustrates a schematic view of the film stack of FIG. 3 after etching a layer in the stack according to embodiments described herein.

FIG. 5 illustrates a schematic view of the film stack of FIG. 4 after etching a layer in the stack and an enlarged view of a sidewall of a patterned portion of the film stack according to embodiments described herein.

FIG. 6 illustrates a schematic view of the film stack of FIG. 5 after etching a layer in the stack according to embodiments described herein.

FIG. 7 illustrates operations of a method for etching a film stack according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Device structures and methods for fabricating device structures are provided herein. Magneto-resistive random access memory (MRAM) devices described herein may include a film stack comprising a magnetic tunneling junction layer, a dielectric capping layer, an etch stop layer, a conductive hard mask layer, a dielectric hard mask layer, a spin on carbon layer, and an anti-reflective coating layer. The film stack may be etched by one or more selected chemistries to achieve improved film stack sidewall verticality. Memory cells having increasingly uniform and reduced critical dimensions may be fabricated utilizing the methods and devices described herein.

The various layers of the film stack may be utilized as hard masks for patterning the stack. The materials of the hard masks and etching chemistries utilized to etch the film stack may provide for improved etch selectivity which results in an improved sidewall verticality profile of features and structures formed on the film stack. With improved etching characteristics, high density MRAM device applications may be achieved. It is contemplated that one or more of the hard masks of the film stack may also improve performance of magnetic tunnel junctions.

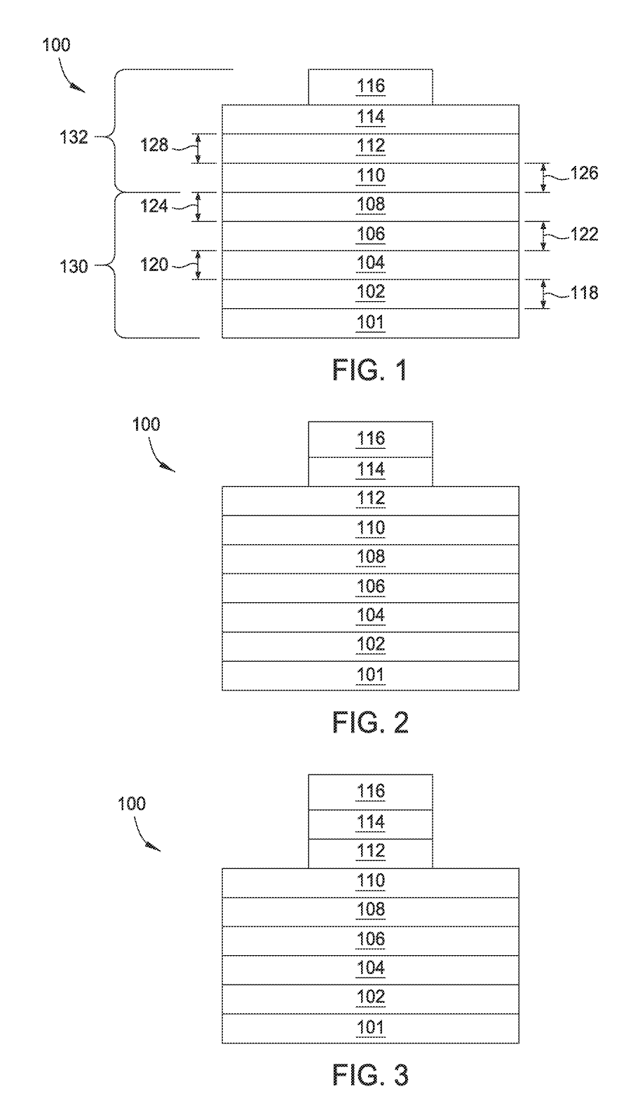

FIG. 1 illustrates a schematic view of a film stack 100. The film stack 100 includes: a substrate 101, an MTJ stack 102, a dielectric capping layer 104, an etch stop layer 106, a conductive had mask layer 108, a dielectric hard mask layer 110, a spin on carbon layer 112, and an anti-reflective coating layer 114. A photoresist layer 116 may also be included in the film stack 100. Generally, a the substrate 101, the MTJ stack 102, the dielectric capping layer 104, the etch stop layer 106, and the conductive hard mask layer 108 form a device portion of an MRAM device. The dielectric hard mask layer 110, the spin on carbon layer 112, the anti-reflective coating layer, and the photoresist layer 116 generally form a patterning portion 132 utilized to pattern the device portion 130. The various layers included in the patterning portion 132 are removed during or after patterning of the device portion 130.

The substrate 101 is generally formed from a conductive or semiconductive material. In one embodiment, the substrate 101 is a bottom electrode for an STT-MRAM device. The MTJ stack 102 may be formed on and in contact with the substrate 101. The MTJ stack 102 may be a single layer structure or a multi-layer structure. For example, the MTJ stack 102 may include various sub-layers arranged in a stack, such as a magnetic storage layer, a tunnel barrier layer, a magnetic reference layer, and an optional pinning layer. The MTJ stack 102 may be formed from one or more materials, including cobalt containing materials, iron containing materials, nickel containing materials, manganese containing materials, ruthenium containing materials, tantalum containing materials, platinum containing materials, boron containing materials, oxygen containing materials, and combinations and mixtures thereof.

In one embodiment, the magnetic storage sub-layer of the MTJ stack 102 may include a first cobalt:iron:boron material layer, a first tantalum material layer, and a second cobalt:iron:boron material layer. The tunnel barrier sub-layer may include a magnesium oxide material and the magnetic reference sub-layer may include a third cobalt:iron:boron material layer, a second tantalum material layer, a first cobalt material layer, and a first cobalt/platinum material layer. The optional pining sub-layer may include a second cobalt material layer, a second cobalt/platinum material layer, a platinum material layer, and a bottom contact. In certain embodiments, the bottom contact may be the substrate 101 or the bottom contact may be an additional material layer formed on the substrate 101. In one embodiment, a ruthenium material layer may be disposed between the magnetic reference sub-layer and the optional pinning sub-layer.

In the embodiment described above, the optional pinning sub-layer may be disposed on and in contact with the substrate 101 and the magnetic reference sub-layer may be disposed on and in contact with the optional pinning sub-layer. In certain embodiments, the ruthenium material layer may be disposed between the optional pinning sub-layer and the magnetic reference sub-layer. The tunnel barrier sub-layer may be disposed on an in contact with the magnetic reference sub-layer and the magnetic storage sub-layer may be disposed on an in contact with the tunnel barrier layer. The dielectric capping layer 104 may be disposed on an in contact with the magnetic storage sub-layer.

In one embodiment, the MTJ stack 102 may contain cobalt containing materials, boron containing materials, and combinations thereof at the interface of the MTJ stack 102 and the dielectric capping layer 104. Alternatively, the MTJ stack 102 may contain cobalt containing materials, boron containing material, iron containing materials, and combinations thereof at the interface of the MTJ stack 102 and the dielectric capping layer 104. A thickness 118 of the MTJ stack 102 may be between about 100 Å and about 1000 Å.

The dielectric capping layer 104 maybe be formed on and in contact with the MTJ stack 102. Generally, the dielectric capping layer 104 may be formed from a dielectric material. For example, the dielectric capping layer 104 may be formed from one or more of a magnesium oxide material, an aluminum oxide material, a zinc oxide material, a titanium oxide material, a tantalum oxide material, a tantalum nitride material, and combinations and mixtures thereof. A thickness 120 of the dielectric capping layer 104 may be between about 5 Å and about 20 Å, for example, between about 8 Å and about 12 Å.

The dielectric capping layer 104 may be configured to improve the interfacial perpendicular magnetic anisotropy of the MTJ stack 102 by providing an additional magnetic metal (MTJ stack 102) and dielectric material (dielectric capping layer 104) interface. As such, the coercive field of the MTJ stack 102 may be increased which provides for improved thermal stability of the MTJ device. In addition, the dielectric capping layer 104 may prevent the diffusion of metals from various other layers in the film stack 100 from diffusing into the MTJ layer 104. Thus, a more pure magnetic/dielectric interface may be maintained and the coercive field may be improved.

The etch stop layer 106 may be formed on and in contact with the dielectric capping layer 104. The etch stop layer 106 may be a single layer or multiple layers of the same or different materials. Generally, the etch stop layer 106 may be formed from a metallic material. For example, the etch stop layer 106 may be formed from one or more layers of a ruthenium containing material, a tungsten containing material, a tantalum containing material, a platinum containing material, a nickel containing material, a cobalt containing material, and combinations and mixtures thereof. A thickness 122 of the etch stop layer 106 may be between about 5 Å and about 50 Å, for example, between about 10 Å and about 20 Å. The etch stop layer 106 is configured to prevent etching of the underlying dielectric capping layer 104 during etching processes. By preventing or reducing the probability of etching the dielectric capping layer 104, the increased coercive field of the MTJ stack 102 may be maintained.

The conductive hard mask layer 108 may be formed on an in contact with the etch stop layer 106. Generally, the conductive hard mask layer 108 is formed from an electrically conductive material. For example, the conductive hard mask layer 108 may be formed from one or more of a tantalum containing material, a tantalum nitride containing material, a titanium containing material, a titanium nitride containing material, a tungsten containing material, a tungsten nitride containing material, and combinations and mixtures thereof. A thickness 124 of the conductive hard mask layer 108 may be between about 400 Å and about 1000 Å, for example, between about 700 Å and about 900 Å. The conductive hard mask layer 108 may be configured to function as a chemical mechanical polishing (CMP) stop during MTJ device formation processes. In addition, the conductive hard mask layer 108 may be configured to function as a top contact in a MTJ device.

The dielectric hard mask layer 110 may be formed on and in contact with the conductive hard mask layer 108. Generally, the dielectric hard mask layer 110 is formed from a dielectric material. For example, the dielectric hard mask layer 110 may be formed from one or more of a silicon oxide containing material, an aluminum oxide containing material, a silicon nitride containing material, and combinations and mixtures thereof. A thickness 126 of the dielectric hard mask layer 110 may be between about 400 Å and about 1000 Å, for example, between about 500 Å and about 700 Å.

The spin on carbon layer 112 may be formed on an in contact with the dielectric hard mask layer 110. Generally, the spin on carbon layer 112 is an amorphous carbon containing material. The spin on carbon layer 112 may have a thickness 128 of between about 500 Å and about 2500 Å, for example, between about 1000 Å and about 2000 Å, such as between about 1250 Å and about 1750 Å. The spin on carbon layer 112 may be utilized to achieve improved etch selectivity and for critical dimension uniformity control. In one embodiment, the spin on carbon layer 112 may be patterned to generate a MTJ device having a pitch between adjacent MTJ devices of less than about 500 nm, for example, between about 50 nm and about 250 nm.

The anti-reflective coating layer 114 may be formed on and in contact with the spin on carbon layer 112. Generally, the anti-reflective coating layer 114 is either an organic or an inorganic material. In one embodiment, the anti-reflective coating layer 114 may be a silicon-containing inorganic material. For example, the anti-reflective coating layer 114 may be a silicon nitride material, a silicon oxynitride material, a silicon carbide material, and combinations and mixtures thereof. In this embodiment, the anti-reflective coating layer 114 may be a silicon rich material. For example, the inorganic material may have a silicon content by weight percentage greater than about 50% silicon, such as greater than about 75% silicon.

The photoresist layer 116 may be formed on and in contact with the anti-reflective coating layer 114. Generally, the photoresist layer 116 is a photosensitive material suitable for patterning via exposure to electromagnetic radiation in photolithography processes, such as 193 nm photolithography processes. It is contemplated that the material utilized for the photoresist layer 116 may be suitable for patterning device structures having pitch dimensions less than about 400 nm, such as devices having pitch dimensions of less than about 200 nm, for example, about 130 nm.

Generally, a device portion 130 of the film stack 100 may include the substrate 101, the MTJ stack 102, the dielectric capping layer 104, the etch stop layer 106, and the conductive hard mask layer 108. The layers of the device portion 130 may remain as structures within an MTJ device. A patterning portion 132 of the film stack may include the dielectric hard mask layer 110, the spin on carbon layer 112, the anti-reflective coating layer 114, and the photoresist layer 116. The layers of the patterning portion 132 may be utilized to pattern the layers of the device portion 130 and the patterning portion 132 may be removed such that the patterning portion layers are not included in an MTJ device.

The substrate 101 and layers 102, 104, 106, 108, 110, 112, 114, and 116, which form the film stack 100, may be selected to provide improved etch selectivity and performance when performing etching processes on the film stack 100. It is contemplated that various material modification processes, such as doping processes, may be performed during formation of the film stack 100 to improve etching characteristics of the layers 102, 104, 106, 108, 110, 112, 114, and 116. For example, material modification processes may be utilized to improve sidewall verticality profiles of the various film stack layers.

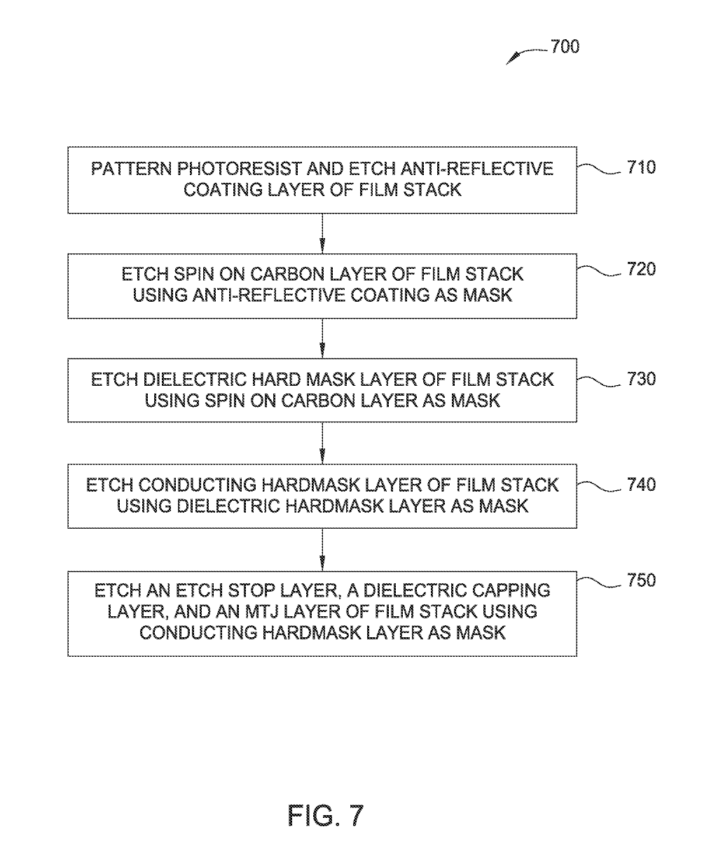

FIG. 7, which illustrates operations of a method 700 for etching the film stack 100, will be discussed concurrently with FIGS. 2-6. The etching processes described below may be performed in a dry plasma etching chamber, such as a reactive ion etching chamber. One example of a suitable chamber is the ADVANTEDGE MESA chamber, available from Applied Materials, Inc., Santa Clara, Calif. It is contemplated that the etching processes described herein may be performed on other suitable configured apparatus from other manufacturers.

FIG. 2 illustrates a schematic view of the film stack 100 of FIG. 1 after etching a layer in the film stack 100 according to embodiments described herein. At operation 710, the photoresist layer 116 may be patterned and the anti-reflective coating layer 114 may be etched. The etching processing parameters may be tuned or otherwise configured to fabricate an MTJ device structure having a desired pitch and critical dimensions.

In one embodiment, processing gases, such as O₂, CHF₃, and CF₄ may be utilized to etch the anti-reflective coating layer 114. The O₂ gas may be provided at a flow rate of between about 1 sccm and about 50 sccm, such as about 10 sccm. The CHF₃ gas may be provided at a flow rate of between about 50 sccm and about 150 sccm, such as about 100 sccm. The CF₄ gas may be provided at a flow rate of between about 100 sccm and about 200 sccm, such as about 150 sccm. The processing gases may be ionized with a source power of between about 250 W and about 750 W, such as about 500 W. The processing environment may also be biased to direct the process gas ions towards the film stack 100. For example, a bias power of between about 50 W and about 150 W, such as about 80 W, may be utilized. The processing environment may be maintained at a pressure of between about 1 mTorr and about 10 mTorr, such as about 4 mTorr. The etching of the anti-reflective coating layer 114 may be performed for an amount of time between about 5 seconds and about 60 seconds, such as between about 20 seconds and about 30 seconds, for example about 21 seconds.

In another embodiment, processing gases, such as CHF₃ and CF₄ may be utilized to etch the anti-reflective coating layer 114. The CHF₃ gas may be provided at a flow rate of between about 50 sccm and about 150 sccm, such as about 100 sccm. The CF₄ gas may be provided at a flow rate of between about 100 sccm and about 200 sccm, such as about 150 sccm. The processing gases may be ionized with a source power of between about 250 W and about 750 W, such as about 500 W. The processing environment may also be biased to direct the process gas ions towards the film stack 100. For example, a bias power of between about 50 W and about 150 W, such as about 80 W, may be utilized. The processing environment may be maintained at a pressure of between about 1 mTorr and about 10 mTorr, such as about 4 mTorr. The etching of the anti-reflective coating layer 114 may be performed for an amount of time between about 5 seconds and about 60 seconds, such as between about 20 seconds and about 30 seconds, for example, about 25 seconds.

In the embodiments described above, it is contemplated that the photoresist layer 116 may remain disposed on the anti-reflective coating layer 114 after etching the anti-reflective coating layer 114 or the photoresist layer 116 may be removed prior to subsequent etching processes.

FIG. 3 illustrates a schematic view of the film stack 100 of FIG. 2 after etching a layer in the film stack 100 according to embodiments described herein. At operation 720, the spin on carbon layer 112 of the film stack 100 may be etched utilizing the anti-reflective coating layer 114 as a mask. It is contemplated that etching the spin on carbon layer 112 may be utilized as process to reduce the critical dimensions of any subsequently formed MTJ device structure.

In one embodiment, processing gases, such as Cl₂, HBr, O₂ and N₂ may be utilized to etch the spin on carbon layer 112. The Cl₂ gas may be provided at a flow rate of between about 10 sccm and about 50 sccm, such as about 25 sccm. The HBr gas may be provided at a flow rate of between about 100 sccm and about 300 sccm, such as about 200 sccm. The O₂ gas may be provided at a flow rate of between about 10 sccm and about 100 sccm, such as about 50 sccm. The N₂ gas may be provided at a flow rate of between about 100 sccm and about 200 sccm, such as about 150 sccm. The processing gases may be ionized with a source power of between about 500 W and about 1500 W, such as about 800 W. The processing environment may also be biased to direct the process gas ions towards the film stack 100. For example, a bias power of between about 150 W and about 300 W, such as about 225 W, may be utilized. The processing environment may be maintained at a pressure of between about 1 mTorr and about 20 mTorr, such as about 10 mTorr. The etching of the spin on carbon layer 112 may be performed for an amount of time between about 5 seconds and about 60 seconds, such as between about 20 seconds and about 30 seconds, for example, about 25 seconds.

In another embodiment, processing gases, such as Cl₂, HBr, O₂ and N₂ may be utilized to etch the spin on carbon layer 112. The Cl₂ gas may be provided at a flow rate of between about 10 sccm and about 50 sccm, such as about 25 sccm. The HBr gas may be provided at a flow rate of between about 200 sccm and about 400 sccm, such as about 300 sccm. The O₂ gas may be provided at a flow rate of between about 10 sccm and about 100 sccm, such as about 50 sccm. The N₂ gas may be provided at a flow rate of between about 100 sccm and about 200 sccm, such as about 150 sccm. The processing gases may be ionized with a source power of between about 500 W and about 1500 W, such as about 800 W. The processing environment may also be biased to direct the process gas ions towards the film stack 100. For example, a bias power of between about 100 W and about 250 W, such as about 175 W, may be utilized. The processing environment may be maintained at a pressure of between about 1 mTorr and about 20 mTorr, such as about 10 mTorr. The etching of the spin on carbon layer 112 may be performed for an amount of time between about 15 seconds and about 90 seconds, such as between about 40 seconds and about 60 seconds, for example, about 50 seconds.

In the embodiments described above, it is contemplated that the anti-reflective coating layer 114 may remain disposed on the spin on carbon layer 112 after etching the spin on carbon layer 112 or the anti-reflective coating layer 114 may be removed prior to subsequent etching processes.

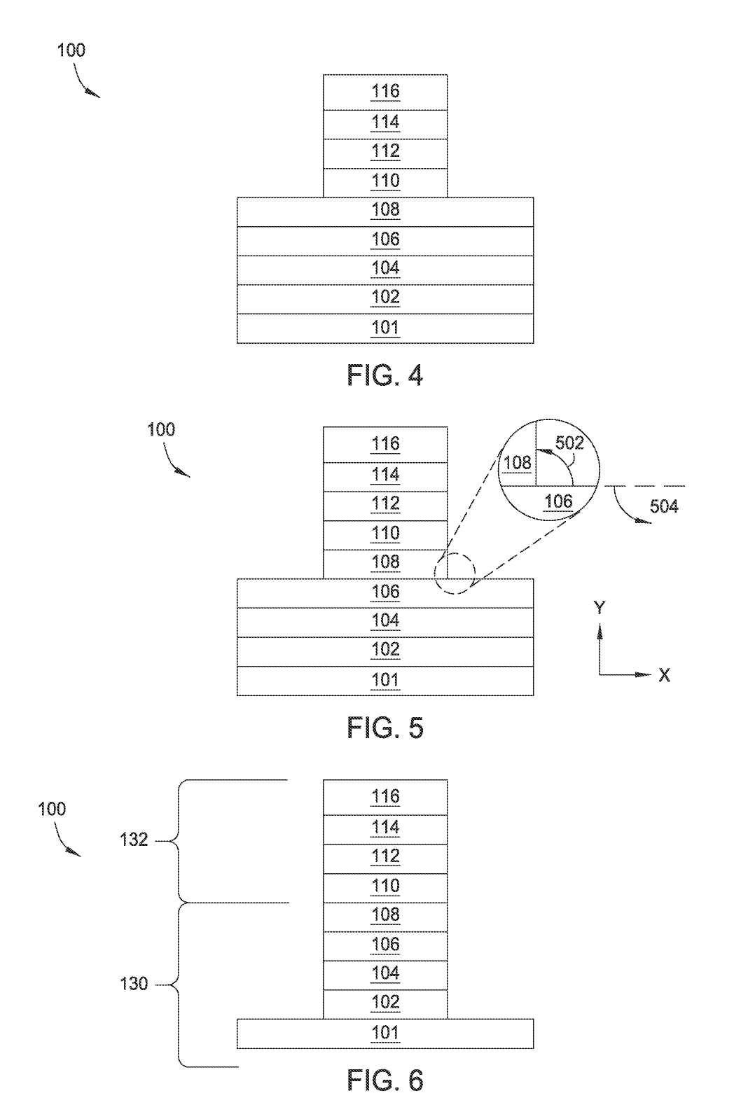

FIG. 4 illustrates a schematic view of the film stack 100 of FIG. 3 after etching a layer in the film stack 100 according to embodiments described herein. At operation 730, the dielectric hard mask layer 110 of the film stack 100 may be etched utilizing the spin on carbon layer 112 as a mask.

In one embodiment, processing gases, such as O₂ and CHF₃, may be utilized to etch the dielectric hard mask layer 110. The O₂ gas may be provided at a flow rate of between about 5 sccm and about 50 sccm, such as about 10 sccm. The CHF₃ gas may be provided at a flow rate of between about 200 sccm and about 400 sccm, such as about 300 sccm. The processing gases may be ionized with a source power of between about 200 W and about 400 W, such as about 300 W. The processing environment may also be biased to direct the process gas ions towards the film stack 100. For example, a bias power of between about 250 W and about 750 W, such as about 500 W, may be utilized. The processing environment may be maintained at a pressure of between about 1 mTorr and about 10 mTorr, such as about 4 mTorr. The etching of the dielectric hard mask layer 110 may be performed for an amount of time between about 50 seconds and about 150 seconds, such as between about 90 seconds and about 110 seconds, for example, about 100 seconds. In another embodiment, the processing parameters described above may be utilized for an amount of time between about 10 seconds and about 60 seconds, such as between about 30 second and about 50 seconds, for example, about 40 seconds.

In the embodiments described above, it is contemplated that the spin on carbon layer 112 may remain disposed on the dielectric hard mask layer 110 after etching the dielectric hard mask layer 110 or the spin on carbon layer 112 may be removed prior to subsequent etching processes.

FIG. 5 illustrates a schematic view of the film stack 100 of FIG. 4 after etching a layer in the film stack 100 and an enlarged view of a sidewall of the patterned portion 132 of the film stack 100 according to embodiments described herein. At operation 740, the conductive hard mask layer 108 of the film stack 100 may be etched utilizing the dielectric hard mask layer 110 as a mask.

In one embodiment, a processing gas, such as CF₄, may be utilized to etch the conductive hard mask layer 108. The CF₄ gas may be provided at a flow rate of between about 25 sccm and about 75 sccm, such as about 50 sccm. The process gas may be ionized with a source power of between about 250 W and about 750 W, such as about 500 W. The processing environment may also be biased to direct the process gas ions towards the film stack 100. For example, a bias power of between about 10 W and about 100 W, such as about 25 W, may be utilized. The processing environment may be maintained at a pressure of between about 1 mTorr and about 10 mTorr, such as about 5 mTorr. The etching of the conductive hard mask layer 108 may be performed for an amount of time between about 60 seconds and about 180 seconds, such as between about 100 seconds and about 130 seconds, for example, about 120 seconds. In another embodiment, the processing parameters described above may be utilized for an amount of time between about 60 seconds and about 180 seconds, such as between about 130 second and about 150 seconds, for example, about 140 seconds.

In the embodiments described above, it is contemplated that the dielectric hard mask layer 110 may remain disposed on the conductive hard mask layer 108 after etching the conductive hard mask layer 108 or the dielectric hard mask layer 110 may be removed prior to subsequent etching processes.

A sidewall profile of the conductive hard mask layer 108 may be substantially vertical. As utilized herein, the term vertical is not an absolute direction, rather, the term vertical may describe the relationship of sidewalls relative to other layers in the film stack 100. For example, an angle 502 defined between the etch stop layer 106 and the etched sidewall of the conductive hard mask layer 108 be greater than about 75° relative to a datum plane 504. The datum plane 504 may be parallel to an interface between the etch stop layer 106 and the conductive hard mask layer 108. In one embodiment, the angle 502 may be greater than about 80°, such as greater than about 85°. It is contemplated that the verticality profile of the etched layers in the film stack 100 may provide for improved MTJ device structure density by reducing the pitch dimensions between adjacent MTJ device structures on a substrate.

FIG. 6 illustrates a schematic view of the film stack 100 of FIG. 5 after etching layers in the film stack 100 according to embodiments described herein. At operation 750, the etch stop layer 106, the dielectric capping layer 104, and the MTJ stack 102 of the film stack 100 may be etched utilizing the conductive hard mask layer 108 as a mask. Suitable etchants and processing parameters for etching the metallic materials of the layers 106, 104, 102 may be utilized to etch the layers 106, 104, 102 until the substrate 101 is exposed. For example, the layers 106, 104, 102 may be etched utilizing processing gases including argon, xenon, krypton, methanol, hydrogen, carbon monoxide, carbon dioxide, and combinations thereof. The resulting device portion 130 may include the substrate 101, the MTJ stack 102, the dielectric capping layer 104, the etch stop layer 106, and the conductive hard mask layer 108. Thus, the benefits provided by the dielectric capping layer 104 may be preserved by incorporation of the dielectric capping layer 104 in the device portion 130 of an MTJ device structure.

Accordingly, an MTJ device structure utilizing the film stack 100 and etching processes described herein may provide for improved device density as a result of improved sidewall verticality profiles of etched layers within the film stack. Thus, pitch and critical dimensions may be reduced. The coercive field of a resulting MTJ device structure may also be improved and interlayer diffusion may be reduced or prevented.

While the foregoing is directed to embodiments of the present disclosure, other and further embodiments of the disclosure may be devised without departing from the basic scope thereof, and the scope thereof is determined by the claims that follow.

What is claimed is:

1. A film stack, comprising:
a magnetic tunneling junction stack;
a dielectric capping layer disposed on the magnetic tunneling junction stack;
an etch stop layer disposed on the dielectric capping layer;
a conductive hard mask layer disposed on the etch stop layer;
a dielectric hard mask layer disposed on the conductive hard mask layer;
a spin on carbon layer disposed on the dielectric hard mask layer; and
an anti-reflective coating layer disposed on the spin on carbon layer.

2. The film stack of claim 1, further comprising:
a bottom electrode disposed on a substrate, wherein the magnetic tunneling junction stack of the film stack is disposed on the substrate.

3. The film stack of claim 2, further comprising:
a photoresist layer disposed on the anti-reflective coating layer.

4. The film stack of claim 1, wherein the dielectric capping layer is formed from a magnesium oxide material, an aluminum oxide material, a zinc oxide material, a titanium oxide material, a tantalum oxide material, a tantalum nitride material, or combinations thereof.

5. The film stack of claim 1, wherein the etch stop layer is formed from a ruthenium containing material, a tungsten containing material, a tantalum containing material, a platinum containing material, a nickel containing material, a cobalt containing material, or combinations thereof.

6. The film stack of claim 1, wherein the conductive hard mask layer is formed from a tantalum containing material, a tantalum nitride containing material, a titanium containing material, a titanium nitride containing material, a tungsten containing material, a tungsten nitride containing material, or combinations thereof.

7. The film stack of claim 1, wherein the dielectric hard mask layer is formed from a silicon oxide containing material, an aluminum oxide containing material, a silicon nitride containing material, or combinations thereof.

8. The film stack of claim 1, wherein the dielectric capping layer is configured to protect the magnetic tunneling junction layer from diffusion of metallic ions from other layers in the film stack.

9. A film stack, comprising:
a magnetic tunneling junction layer;
a dielectric capping layer having a thickness of between about 5 Å and about 20 Å disposed on the magnetic tunneling junction layer;
an etch stop layer having a thickness of between about 5 Å and about 50 Å disposed on the dielectric capping layer;
a conductive hard mask layer having a thickness of between about 400 Å and about 1000 Å disposed on the etch stop layer;
a dielectric hard mask layer disposed on the conductive hard mask layer;
a spin on carbon layer disposed on the dielectric hard mask layer; and
an inorganic silicon containing anti-reflective coating layer disposed on the spin on carbon layer.

10. The film stack of claim 9, wherein the dielectric hard mask layer has a thickness of between about 400 Å and about 1000 Å.

11. The film stack of claim 9, wherein the spin on carbon layer has a thickness of between about 500 Å and about 2500 Å.

12. The film stack of claim 9, wherein a sidewall of the conductive hard mask layer has a sidewall angle greater than about 85° relative to a horizontal datum plane.

13. The film stack of claim 12, wherein the sidewall angle is achieved on magnetic tunnel junction devices having a pitch of between about 100 nm to and about 400 nm.

14. The film stack of claim 9, wherein the dielectric capping layer is configured to improve an interfacial perpendicular magnetic anisotropy of the magnetic tunneling junction layer.

15. A method of etching a film stack, comprising:
patterning a photoresist layer and etching an anti-reflective coating layer of a film stack;
etching a spin on carbon layer of the film stack using the anti-reflective coating layer as first a mask;
etching a dielectric hard mask layer of the film stack using the spin on carbon layer as second mask;
etching a conductive hard mask layer of the film stack using the dielectric hard mask layer as a third mask;
etching an etch stop layer of the film stack using the conductive hardmask layer as a fourth mask to expose a dielectric capping layer of the film stack, wherein the dielectric capping layer is disposed on a magnetic tunneling junction layer.

16. The method of claim 15, wherein the etching the anti-reflective coating layer comprises utilizing processing gases selected from the group consisting of O₂, CHF₃, CF₄, and combinations and mixtures thereof.

17. The method of claim 15, wherein the etching the spin on carbon layer comprises utilizing processing gases selected from the group consisting of Cl₂, HBr, O₂, N₂, and combinations and mixtures thereof.

18. The method of claim 15, wherein the etching the dielectric hard mask layer comprises utilizing processing gases selected from the group consisting of O₂, CF₄, CHF₃, and combinations and mixtures thereof.

19. The method of claim 15, wherein the etching the conductive hard mask layer comprises utilizing processing gases selected from the group consisting of CF₄, CHF₃, and combinations and mixtures thereof.

20. The method of claim 19, wherein the etching the conductive hard mask layer results in a sidewall of the conductive hard mask layer having a sidewall angle greater than about 85° relative to a horizontal datum plane.
